(19) United States
(12) Patent Application Publication
(10) Pub. No.: US 2016/0013266 A1
(43) Pub. Date: Jan. 14, 2016

(54) VERTICAL SEMICONDUCTOR DEVICE

(71) Applicant: Jun OKAWARA, Miyoshi-shi (JP)

(72) Inventor: Jun OKAWARA, Miyoshi-shi (JP)

(73) Assignee: TOYOTA JIDOSHA KABUSHIKI KAISHA, Toyota-shi, Aichi-ken (JP)

(21) Appl. No.: 14/772,426

(22) PCT Filed: Mar. 27, 2013
(86) PCT No.: PCT/JP2013/059023

§ 371 Date: Sep. 3, 2015

(51) Int. Cl. H01L 29/06; H01L 29/36; H01L 29/861; H01L 29/739; H01L 29/78

(52) U.S. Cl. CPC H01L 29/0619; H01L 29/7395; H01L 29/7827; H01L 29/861; H01L 29/36

(57) ABSTRACT

In a structure which secures a breakdown voltage of a semiconductor device by providing a channel stop region to a boundary part between an outer circumferential side surface and a front surface of the semiconductor substrate, the channel stop region is formed by a plurality of regions having different impurity concentrations. Upon this occasion, the channel stop region satisfies following relations: the impurity concentrations of the plurality of the regions are higher for regions closer to the outer circumferential side surface of the semiconductor substrate; and a depth of a high-impurity-concentration region is equal to or deeper than a depth of a low-impurity-concentration region. Electric field concentration is alleviated around the channel stop region and a breakdown voltage of the semiconductor substrate increases.

### TECHNICAL FIELD

This specification discloses a vertical semiconductor device in which a change in an electrical resistance occurs between a front-surface electrode formed on a front surface of a semiconductor substrate and a back-surface electrode formed on a back surface of the semiconductor substrate, as a result of which switching can be performed between an on-state where an electrical current flows between the front-surface electrode and the back-surface electrode and an off-state where the electrical current does not flow therebetween.

### BACKGROUND ART

A vertical semiconductor device mentioned above is disclosed in Patent Literature 1. A vertical semiconductor device disclosed in Patent Literature 1 includes a gate electrode, and switching between an on-state and an off-state is performed according to a voltage applied to the gate electrode. In the case of a diode, the on-state is established when a forward voltage is applied, and the off-state is established when a reverse voltage is applied. In the vertical semiconductor device used for power control, a large voltage difference is created between the front-surface electrode and the back-surface electrode. When the semiconductor device is in the off-state, the front-surface electrode and the back surface electrode need to be electrically shut off (electrically insulated) against the large voltage difference.

The semiconductor device is formed on a semiconductor substrate having a finite size. As the voltage difference created between the front-surface electrode and the back-surface electrode becomes large, a phenomenon where an electrical current flows between the front surface electrode and the back surface electrode via the peripheral region of the semiconductor substrate arises. Accordingly, a technique has been widely used as follows: a semiconductor structure, in which on/off switching is actively performed by using a gate electrode, or a semiconductor structure, in which rectifying operation is performed by using a PN junction or the like is arranged at a center of the semiconductor substrate; a breakdown voltage structure is arranged in a region which circles a semiconductor structure mentioned above (that is, in a region extending along the periphery of the semiconductor substrate). Here, the breakdown voltage structure refers to a structure in which an electrical current is suppressed and is prevented from flowing between the front-surface electrode and the back-surface electrode if a large voltage difference is created between the front-surface electrode and the back-surface electrode while the semiconductor device is in the off-state.

As shown in FIGS. 6 and 7, a peripheral breakdown voltage structure in Patent Literature 1 includes a guard ring, which encircles the outer circumference of the center region 28 of a semiconductor substrate 12, and a channel stop region, which encircles the outer circumference of the guard ring. In the case of Patent Literature 1, five-fold guard rings 14 are utilized (two outer guard rings 14d, 14e among the five guard rings 14 are shown in FIG. 7), and a channel stop region 10 is formed with two regions 10g, 10h having different impurity concentrations. Field electrodes 18a to 18e are arranged along respective corresponding guard rings 14a to 14e, and a stop electrode 20 is arranged along the channel stop region 10. Five-fold field electrodes 18a to 18e and one-fold stop electrode 20 are shown in FIG. 6.

In the technique of Patent Literature 1, an IGBT is formed in a center region 28. In FIG. 7, reference number 2 refers to a back-surface electrode (a collector electrode) formed on a back-surface of a semiconductor substrate 12, and reference numbers 4 and 8 refer to a p-type collector region and an n-type drift region, respectively. An n-type emitter region (not shown), a p-type body region which separates the n-type emitter region and the n-type drift region 8, a gate electrode which opposes the p-type body region via a gate insulating film, and a front-surface electrode (an emitter electrode) which is formed on the front surface of the semiconductor substrate 12 and which is electrically conducted to the emitter region are formed in the center region. Reference number 16 refers to an insulating film which insulates the gate electrode and the emitter electrode, the emitter electrode and the field electrode 18a, between adjacent field electrodes, and between the field electrode 18e and the stop electrode 20.

If the p-type guard rings 14a to 14e and the field electrodes 18a to 18e are arranged around the center region 28, a depletion layer extends toward the outer circumferential side surface 12a of the semiconductor substrate 12 while the IGBT is in the off-state, thus increasing an insulation breakdown voltage. However, if the depletion layer has reached the outer circumferential side surface 12a of the semiconductor substrate 12, the insulation breakdown voltage decreases. The n-type channel stop region 10 and the stop electrode 20 prevent the depletion layer to reach the outer circumferential side surface 12a of the semiconductor substrate 12. In the technique of Patent Literature 1, the depletion layer is extended toward the outer circumferential side surface 12a of the semiconductor substrate 12 by the p-type guard rings 14a to 14e and the field electrodes 18a to 18e, and the depletion layer is prevented to reach the outer circumferential side surface 12a of the semiconductor substrate 12 by the n-type channel stop region 10 and the stop electrode 20.

In the technique of Patent Literature 1, although there is no disclosure of an object of forming the channel stop region 10 with two regions 10g, 10h having different impurity concentrations, the region 10h having a high impurity concentration is formed in a local area within the region 10g having a low impurity concentration. That is, the high-impurity-concentration region 10h is included in the low-impurity-concentration region 10g when the semiconductor substrate is viewed not only in a plan view but also in a sectional view. That is, the high-impurity-concentration region 10h lies in a depth range shallower than the depth range in which the low-impurity-concentration region 10g lies, thus not contacting with the drift region 8.

### CITATION LIST

### Patent Literature

### [Patent Literature 1] Japanese Patent Application Publication No. 2012-4466

### SUMMARY OF INVENTION

### Technical Problem

According to the breakdown voltage structure of Patent Literature 1, it is possible to prevent the depletion layer extending toward the outer circumferential side surface 12a of the semiconductor substrate 12 to reach the outer circumferential side surface 12a of the semiconductor substrate 12 by the guard rings 14a to 14e and the field electrodes 18a to 18e. On the other hand, according to the technique of Patent Literature 1, there remains a problem that an interval of equipotential lines becomes narrow in the vicinity of the channel stop region 10 where electric field strength increases. In particular, there remains a problem that the interval of equipotential lines becomes narrow in an area 30 adjacent to the corner, i.e. the corner of the channel stop region 10 when viewed in a sectional view, where electric field strength increases.

This specification discloses a technique that decreases electric field strength in the area adjacent to the corner, i.e. the corner when viewed in a sectional view, of the channel stop region to improve breakdown voltage capability.

### Solution to Technical Problem

In a semiconductor device disclosed in this specification, a peripheral breakdown voltage structure is provided in a peripheral region of a semiconductor substrate. The peripheral breakdown voltage structure includes a channel stop region provided in an area which faces both an outer circumferential side surface of the semiconductor substrate and a front surface in continuity to the outer circumferential side surface. On an inner side of the channel stop region, a structure, such as a guard ring or a RESURF structure, which allows a depletion layer to extend toward the outer circumferential side surface of the semiconductor substrate, is provided. In the semiconductor device disclosed in this specification, the channel stop region satisfies the following relations:

(1) the channel stop region is provided with a plurality of regions having different impurity concentrations;

(2) the impurity concentrations are higher at portions closer to the outer circumferential side surface of the semiconductor substrate; and

(3) the depth of a high-impurity-concentration region is equal to or more than the depth of a low-impurity-concentration region.

Here, “equal to or more than” means that the depth of the high-impurity-concentration region is equal to or deeper than the depth of the low-impurity-concentration region. That is, “equal to or more than” means that the depth of the high-impurity-concentration region is not shallower than the depth of the low-impurity-concentration region. Since the impurity concentration becomes higher as the outer circumferential side surface is approached, it may be mentioned that the depth of a channel stop region close to the outer circumferential side surface of the semiconductor substrate is more than the depth of a channel stop region remote from the outer circumferential side surface of the semiconductor substrate.

(1) The channel stop region is configured of the plurality of regions having different impurity concentrations;

(2) the impurity concentrations are higher at the portions closer to the outer circumferential side surface of the semiconductor substrate; and

(3) the depth of the high-impurity-concentration region is not shallower than the depth of the low-impurity-concentration region.

When the above relations are satisfied, electric field strength in an area adjacent to the corner, i.e. the corner when viewed in a sectional view, of the channel stop region is decreased and breakdown voltage capability can be improved.

Also in the technique of Patent Literature 1 shown in FIG. 7, the following relations are satisfied:

(1) the channel stop region is configured of the plurality of regions having different impurity concentrations; and

(2) the impurity concentrations are higher at the portions closer to the outer circumferential side surface of the semiconductor substrate.

However, the high-impurity-concentration region is formed at a shallower depth than the lower-impurity-concentration region, which does not satisfy the relation (3) mentioned above. If the relation (3) is not satisfied, even if the requirements of relations (1), (2) are met, the electric field strength of the area adjacent to the corner, i.e. the corner when viewed in the sectional view, of the channel stop region is increased, and breakdown voltage capability cannot be improved.

### BRIEF DESCRIPTION OF DRAWINGS

FIG. 1 shows a peripheral part of the semiconductor substrate of a first embodiment when viewed in a sectional view;

FIG. 2 is a view showing equipotential lines produced in the semiconductor substrate of FIG. 1;

FIG. 3 is a view showing equipotential lines produced when a channel stop region is configured by a single region;

FIG. 4 shows a peripheral part of the semiconductor substrate of a second embodiment when viewed in a sectional view;

FIG. 5 shows a peripheral part of the semiconductor substrate of a third embodiment when viewed in a sectional view;

FIG. 6 shows the semiconductor substrate of Patent Document 1 when viewed in a plan view;

FIG. 7 shows a peripheral part of the semiconductor device of Patent Literature 1 when viewed in a sectional view; and

FIG. 8 shows views for comparative purposes, which illustrate respective corresponding phenomena produced in a peripheral part of the semiconductor substrate of the first embodiment and of Patent Literature 1.

### DESCRIPTION OF EMBODIMENTS

### First Embodiment

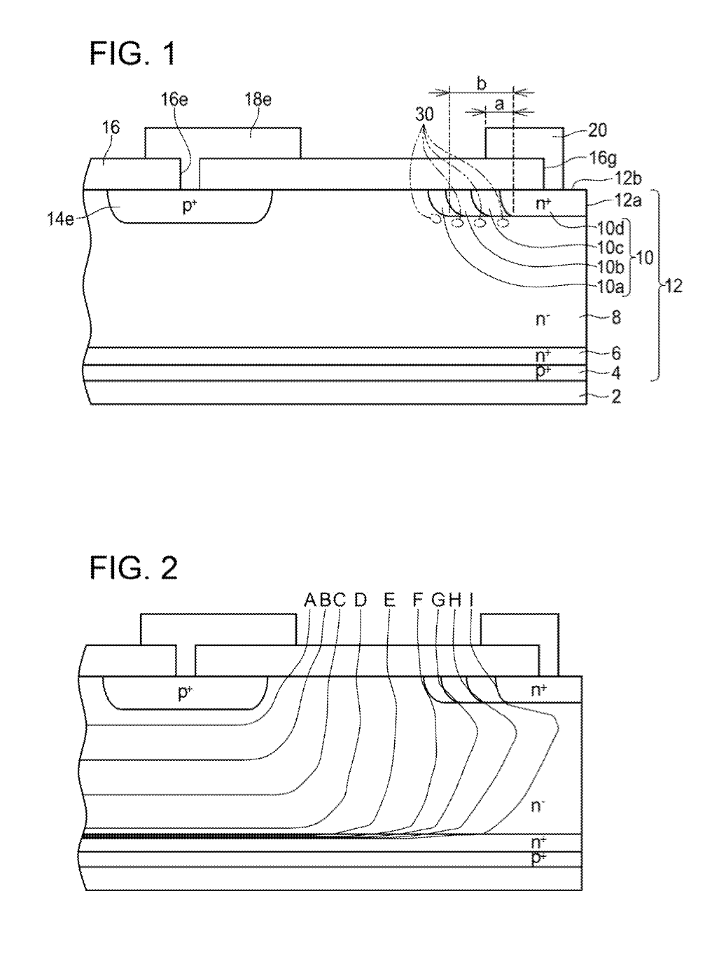

FIG. 1 shows a peripheral part of a semiconductor substrate 12 of a first embodiment when viewed in a sectional view, specifically showing a part on an outer circumferential side surface 12a side with respect to an outermost guard ring 14e. On an inner side of the outermost guard ring 14e, multiple guard rings 14a to 14d (not shown in FIG. 1) are provided, and on a further inner side, a semiconductor structure that operates as an IGBT is provided. These aspects are same as those in a conventional technique, and repeated explanation will be omitted. The IGBT described in Patent Literature 1 utilizes a gate electrode extending along a front surface of the semiconductor substrate, but an IGBT may utilize a trench gate electrode.

In FIG. 1, reference number 12 refers to the semiconductor substrate, and a back-surface electrode (a collector electrode) 2 is disposed on a back surface of the semiconductor substrate 12. Reference number 4 refers to a p-type collector region, and reference number 6 refers to an n-type buffer region, and reference number 8 refers to an n-type drift region. An impurity concentration of the drift region 8 is lower when compared with an impurity concentration of the buffer region 6. The drift region 8 is configured of the semiconductor substrate 12, which remains unprocessed, and may be called a bulk region. An n-type emitter region (not shown), a p-type body region which separates the n-type emitter region and the n-type drift region 8, a gate electrode which opposes the body region via a gate insulating film, and a front-surface electrode (an emitter electrode) which is disposed on a front surface of the semiconductor substrate 12 and which is to be electrically connected to the emitter region are provided on a center region (not shown). Reference number 16 refers to an insulating film, which insulates the gate electrode from the emitter electrode. Reference number 14e refers to the outermost guard ring, and reference number 18e refers to an outermost field electrode. The guard ring 14e and the field electrode 18e are electrically connected to each other via an opening 16e provided in the insulating film 16. Guard rings 14a to 14e are provided as p-type regions.

Reference number 10 refers to a channel stop region provided in an area that faces both an outer circumferential side surface 12a of the semiconductor substrate 12 and a front-surface 12b, which succeeds to the outer circumferential side surface 12a, of the semiconductor substrate 12. The channel stop region 10 is characterized as follows: (1) the region 10 is configured of n-type regions 10a, 10b, 10c, 10d which have different impurity concentrations from one another; (2) the impurity concentrations are higher for regions closer to the outer circumferential side surface 12a of the semiconductor substrate 12. That is, the following relation is satisfied: the impurity concentration of 10a<the impurity concentration of 10b<the impurity concentration of 10c<the impurity concentration of 10d. Even in the region 10a having the lowest impurity concentration among the regions configuring the channel stop region 10, its impurity concentration is higher than that of the drift region 8. That is, the following relation is satisfied: the impurity concentration of the drift region 8<the impurity concentration of region 10a. (3) The depth of a high-impurity-concentration region is not shallower than the depth of a low-impurity-concentration region. That is, the following relation is satisfied: the depth of region 10a≦the depth of region 10b≦the depth of region 10c≦the depth of region 10d. In this embodiment, the following relation is satisfied: the depth of region 10a=the depth of region 10b=the depth of region 10c=the depth of region 10d. If such a relation is assumed, i.e. the depth of the region 10a>the depth of the region 10b>the depth of the region 10c>the depth of the region 10d, the region 10d is included in the region 10c, and the region 10c is included in the region 10b, and the region 10b is included in the region 10a; thus the regions 10b, 10c, 10d do not contact with the drift region 8, and only the region 10a contacts with the drift region 8. In this embodiment, since there is a relation, i.e. the depth of region 10a≦the depth of the region 10b≦the depth of the region 10c≦the depth of the region 10d, each of the regions 10a, 10b, 10c, 10d contacts with the drift region 8. According to this structure, a position at which electric field strength is likely to be high due to dense equipotential lines is distributed to four locations denoted by reference number 30 in FIG. 1, and the electric field strength of each location decreases.

FIG. 2 shows the distribution of equipotential lines A, B, etc. in a condition where an on-voltage is not applied to the gate electrode and where the front-surface electrode is earthed and where a positive voltage is applied to the back-surface electrode. Equipotential lines do not become dense even at the position denoted by the location 30 of FIG. 1, and the electric field strength in the location 30 is suppressed low.

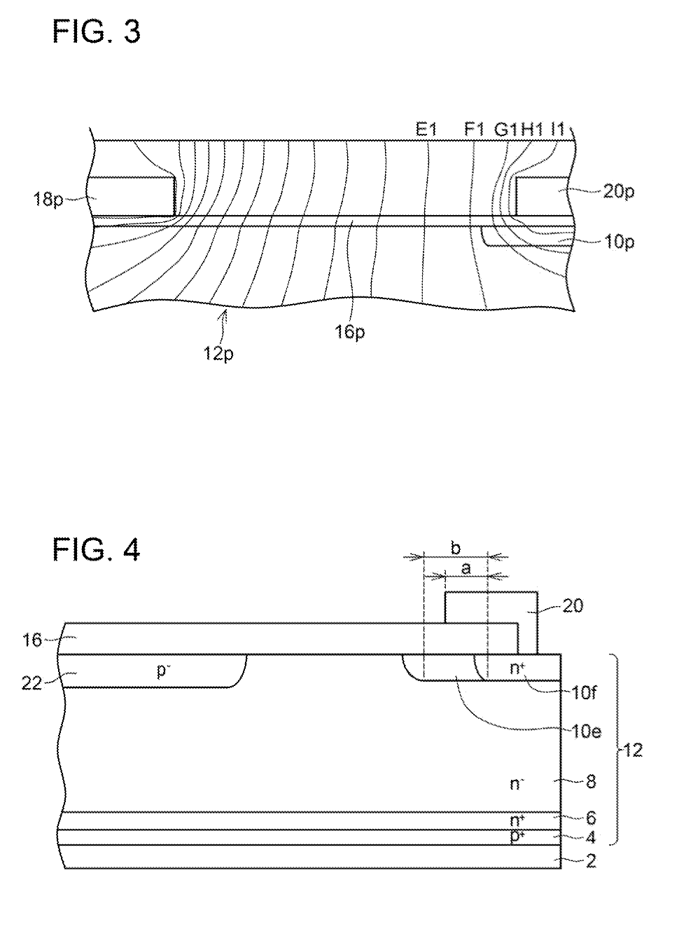

FIG. 3 shows the distribution of equipotential lines produced when a channel stop region 10p is configured by a single region having a uniform impurity concentration. In FIG. 3, equipotential lines G1, H1, I1 passing through the channel stop region 10p are densely arranged, and high electric field strength occurs in the drift region 8 located in the periphery of the channel stop region 10p. If FIG. 2 and FIG. 3 are compared with each other, the following is obvious. That is, when the channel stop region satisfy the relations (1), (2), (3) mentioned above, the maximum value of the electric field strength occurring in the drift region 8 can be suppressed low. It has become unlikely that there occurs a phenomenon where insulation is broken due to excessively high electric field strength.

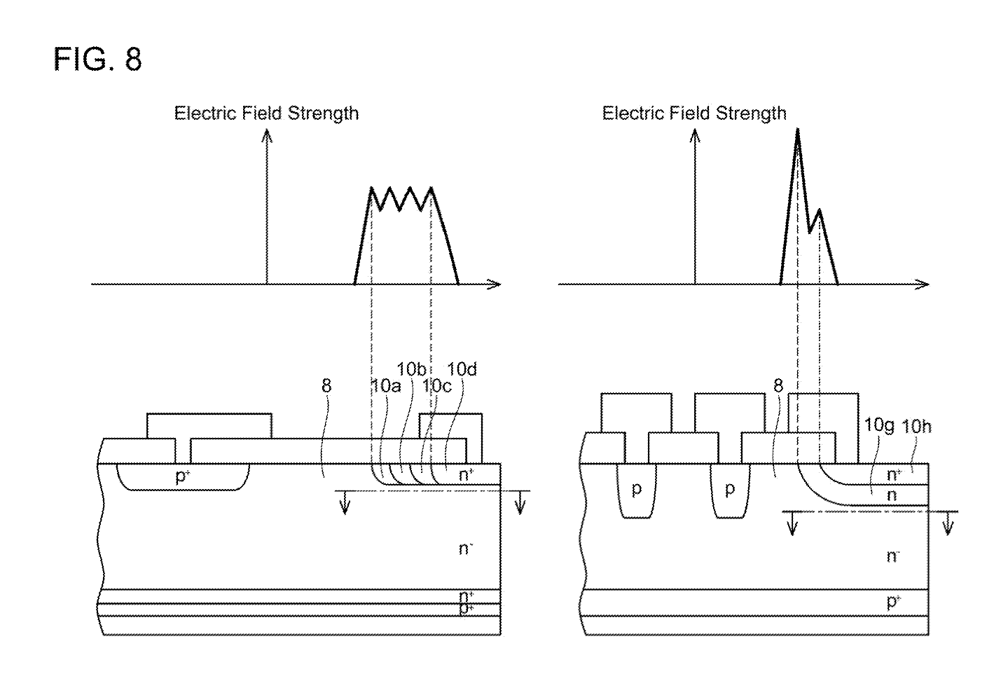

FIG. 8 shows views for comparative purposes, which illustrate respective corresponding phenomena produced in the semiconductor device of the embodiment and in a conventional semiconductor device. Illustration (2) of FIG. 8 shows a sectional view of the semiconductor device of the embodiment shown in FIG. 1, and graph (1) of FIG. 8 shows the distribution of electric field strength along line (1)-(1) of illustration (2). Illustration (4) of FIG. 8 shows a sectional view of the conventional semiconductor device shown in FIG. 7, and graph (3) of FIG. 8 shows the distribution of electric field strength along line (3)-(3) of illustration (4). If graph (1) and graph (3) are compared with each other, the following is obvious. That is, when the impurity concentration of the channel stop region 10 changes on the surface contacting with the drift region 8, as shown in illustration (2), electric field strength decreases in the periphery of a position opposing a boundary where the impurity concentration changes. In the case of the illustration (2), with electric field concentration dispersed in the periphery of positions opposing four positions described below, there can be prevented a phenomenon from occurring, where insulation is broken due to too high electric field strength. Specifically, the four positions include: a position at which varies from the drift region 8 with a low impurity concentration to the channel stop region 10a with a higher impurity concentration; a position at which varies from the region 10a with the lowest impurity concentration among the channel stop region 10 to the region 10b with a higher impurity concentration; a position at which varies from the region 10b to the region 10c with a higher impurity concentration; a position at which varies from the region 10c to the region 10d with a higher impurity concentration. At the same time, an area in graph (1), i.e. a value acquired with the electric field strength integrated along a distance, is increased and high insulation resistance can be obtained. In contrast, as shown in illustration (4), when the impurity concentration of the channel stop region 10 in a surface contacting with the drift region 8 is uniform (the high-impurity-concentration region 10h is included in the low-impurity concentration region 10g, and does not contact with the drift region 8), a phenomenon which electric field concentration is dispersed is obtained only in the periphery of the position at which varies from the drift region 8 with a low impurity concentration to the channel stop region 10g with a higher impurity concentration; electric field strength becomes too high, making it easy to cause a phenomenon where insulation is broken. Although electric field strength also decreases in the periphery of the position at which varies from the region 10g with a low impurity concentration to the region 10h with a higher impurity concentration, the changing point of the impurity concentration does not face the drift region 8, being less effective for dispersing the electric field concentration; as a result, there cannot be suppressed the phenomenon where the maximum value of electric field strength becomes too high. Moreover, an area in graph (3) is smaller than that in graph (1), and insulation resistance is also lower.

According to the structure in which a differences is formed in the impurity concentration in the channel stop region and in which the boundary position of the impurity concentration also contacts the drift region 8, the electric field concentration can be dispersed in the periphery of a position at which the electric field concentration becomes too high. For that reason, the maximum value of electric field strength can be prevented from becoming too high, and also high insulation resistance can be secured by securing an area, which is acquired by integrating the distribution of electric field strength along a distance. That result is reflected in FIG. 2, showing that equipotential lines do not become too dense in the periphery of the channel stop region and that high insulation resistance can be obtained.

As shown in FIG. 1, when it is assumed that a reference position is a position at which switching occurs from region 10c to the region 10d in the surface contacting with the drift region 8 and that “a” is a distance which is measured from the reference position to the extending end of the stop electrode 20 and that “b” is a distance which is measured from the reference position to the extending end of the region 10a (a distance from the reference position to a position at which switching occurs from a flat surface to a curved surface in the bottom surface of the region 10a), a relation of a<b is established. The regions 10a, 10b, etc. extend in the region which is not covered with the stop electrode 20. This also contributes to the dispersion of electric field concentration in the periphery of a position at which electric field becomes too high. As a result, the maximum value of electric field strength is prevented from becoming too high, and also high insulation resistance is effectively secured by securing the area, which is acquired by integrating the distribution of electric field strength along a distance.

### Second Embodiment

As shown in FIG. 4, a peripheral breakdown voltage structure may be configured of a RESURF layer 22 in place of a guard ring 14. A depletion layer can be extended toward the outer circumferential side surface of a semiconductor substrate by utilizing the RESURF layer 22. Moreover, when the channel stop region 10 is configured of a plurality of regions, two regions are included as a minimum case. Also in this case, a relation, i.e. an impurity concentration of the drift region 8<an impurity concentration of the region 10e<an impurity concentration of the region 10f is satisfied; and if a condition where a depth of the region 10f is not shallower than a depth of the region 10e and where the region 10f contacts with the drift region 8 is satisfied, electric field concentration is alleviated around the channel stop region 10 and a high breakdown voltage can be secured.

### Third Embodiment

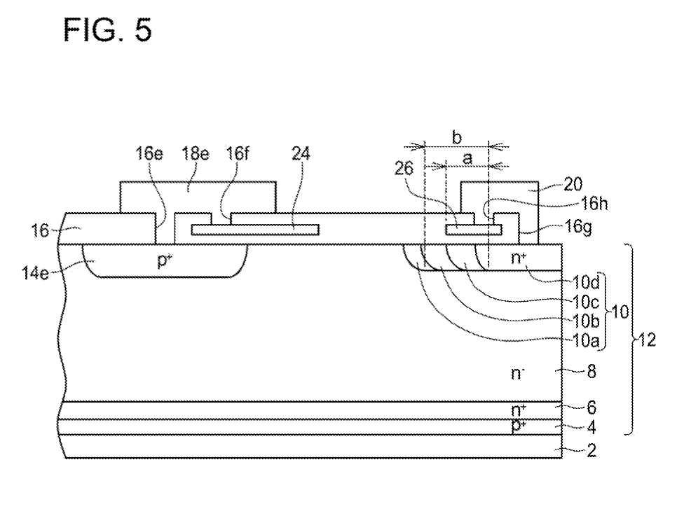

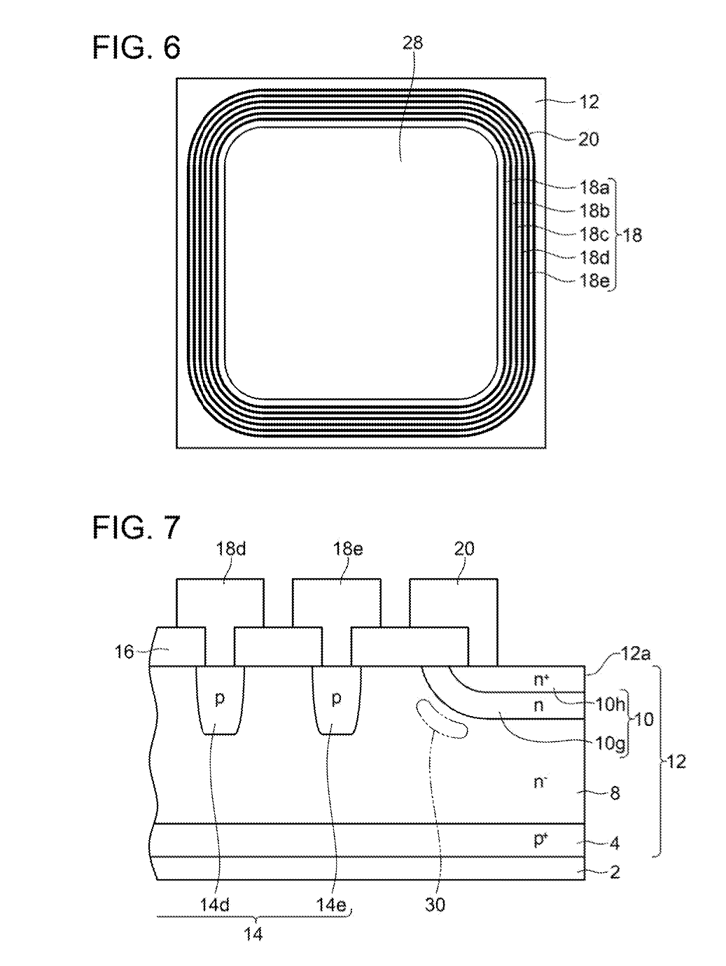

As shown in FIG. 5, a field plate 24 may be utilized in addition to the field electrode 18. This field plate can be formed of polysilicon etc. In that case, an ohmic contact has been made between the field electrode 18 and the field plate 24 by utilizing an opening 16f provided in the insulating film 16. The field plate 24 affects the distribution of electric field in the semiconductor substrate 12, and extends the depletion layer toward the outer circumferential side surface of the semiconductor substrate 12.

Moreover, a stop plate 26 may be utilized in addition to the stop electrode 20. The stop plate can be formed of polysilicon etc. In that case, an ohmic contact has been made between the stop electrode 20 and the stop plate 24 by utilizing the opening 16h provided in the insulating film 16. The stop plate 26 affects the distribution of electric field in the semiconductor substrate 12, and prevents the concentration of electric field around the channel stop region.

Also in this case, when it is assumed that a reference position is a position at which switching occurs from region 10c to the region 10d in the surface contacting with the drift region 8 and that “a” is a distance which is measured from the reference position to the extending end of the stop plate 24 and that “b” is a distance which is measured from the reference position to the extending end of the region 10a (a distance from the reference position to a position at which switching occurs from a flat surface to a curved surface in the bottom surface of the region 10a), a relation of a<b is established. This also contributes to the dispersion of electric field concentration in the periphery of a position at which electric field becomes too high. As a result, the maximum value of electric field strength is prevented from becoming too high, and also high insulation resistance is effectively secured by securing the area, which is acquired by integrating the distribution of electric field strength along a distance.

Although the present Examples have been described in detail, these are merely illustrative and place no limitation on the scope of the patent claims. The technology described in the patent claims also encompasses various changes and modifications to the specific examples described above. For example, although an IGBT is formed at the center of a semiconductor substrate in the embodiment, the peripheral breakdown voltage structure disclosed in this specification is also useful when a MOS or a diode is formed at the center of the semiconductor substrate. Moreover, although an n-type semiconductor substrate is utilized for the drift region in the embodiment, a p-type semiconductor substrate may be utilized for the drift region. A conduction type can be reversed. The technical elements explained in this specification or the drawings provide technical utility either independently or through various combinations, and are not limited to the combinations described at the time the claims are filed. Moreover, the techniques illustrated by this specification or the drawings are to satisfy multiple objectives simultaneously, and satisfying any one of those objectives gives technical utility to the present invention.

### REFERENCE SIGN LIST

2: Back-surface electrode, Collector electrode
4: Collector region
6: Buffer region
8: Drift region, Bulk region
10: channel stop region
10a, 10b, 10c, 10d: Regions with different impurity concentrations
10e, 10f: Regions with different impurity concentrations
12: Semiconductor substrate
12a: Outer circumferential side surface
12b: Front surface
14: Guard ring
16: Insulating film
18: Field electrode
20: Stop electrode
22: RESURF layer
24: Field plate
26: Stop plate
28: Center region
30: Location of electric field concentration

1. A semiconductor device comprising:
a semiconductor substrate;
a front-surface electrode disposed on a front surface of the semiconductor substrate; and
a back-surface electrode disposed on a back surface of the semiconductor substrate;
wherein
a semiconductor structure for current control is provided in a center region of the semiconductor substrate, and
an extending structure, and a channel stop region, and a stop electrode are provided in a peripheral region of the semiconductor substrate,
the semiconductor structure for current control controls a current flowing between the front-surface electrode and the back-surface electrode,
the extending structure allows a depletion layer to extend toward an outer circumferential side surface of the semiconductor substrate when the current is not flowing between the front-surface electrode and the back-surface electrode,
the channel stop region prevents the depletion layer from extending toward the outer circumferential side surface to reach the outer circumferential side surface when the current is not flowing between the front-surface electrode and the back-surface electrode,
the channel stop region satisfies following relations:
(1) the channel stop region is configured of a plurality of regions having different impurity concentrations;
(2) the impurity concentrations of the plurality of the regions are higher for regions closer to the outer circumferential side surface of the semiconductor substrate; and
(3) a depth of a high-impurity-concentration region is equal to or more than a depth of a low-impurity-concentration region, and
the stop electrode extends toward the center region while facing the channel stop region via an insulating layer, from a position where the stop-electrode is configured to be electrically connected with the channel stop region, and
a position of the channel stop region that is closest to the center region is located on a center region side than a position of the stop electrode that is closest to the center region.

2. The semiconductor device according to claim 1, wherein
the depth of the high-impurity-concentration region is equal to the depth of the low-impurity-concentration region.

3. The semiconductor device according to claim 1, wherein
a following relation is satisfied: an impurity concentration of a bulk region of the semiconductor substrate<an impurity concentration of the low-impurity-concentration region configuring the channel stop region<an impurity concentration of the high-impurity-concentration region configuring the channel stop region.
